(19) United States
(12) Patent Application Publication
(10) Pub. No.: US 2009/0031947 A1
(43) Pub. Date: Feb. 5, 2009

(54) Reactor

(75) Inventor: Pekka Soininen, Helsinki (FI)

Correspondence Address: OLIFF & BERRIDGE, PLC, P.O. BOX 320850, ALEXANDRIA, VA, 22320-4850, US

(73) Assignee: BENEQ OY, VANTAA (FI)

(21) Appl. No.: 11/918,137

(22) PCT Filed: Apr. 21, 2006
(86) PCT No.: PCT/FI2006/050158

§ 371 Date: Oct. 10, 2007

(30) Foreign Application Priority Data
Apr. 22, 2005 (FI) 20055188

(51) Int. Cl. C23C 14/24; C23C 14/26

(52) U.S. Cl. 118/50.1; 118/50

(57) ABSTRACT

A reactor for an atomic layer deposition (ALD) method, the reactor comprising a vacuum chamber which has a first end wall provided with a loading hatch, a second end wall provided with a rear flange, side walls/casing connecting the first and the second end walls, and at least one source material fitting for feeding source materials into the vacuum chamber of the reactors. According to the invention, at least one of the source material fittings is provided in the side wall/casing of the vacuum of the reactor.

### BACKGROUND OF THE INVENTION

The invention relates to a reactor according to the preamble of claim 1, and particularly to a reactor for an atomic layer deposition method, the reactor comprising a vacuum chamber having a first end wall provided with an installation hatch, a second end wall provided with a service hatch, side walls/casing connecting the first and the second end walls, and at least one source material fitting for feeding source materials into the vacuum chamber of the reactor.

According to prior art, in reactors used for atomic layer deposition (ALD) methods, source material chemicals have been fed to a reactor's underpressure receptacle, a vacuum chamber, from its first end and, similarly, the reactor has been loaded/unloaded from the opposite end. This has been advantageous since the underpressure receptacle could be manufactured from a tube, which, in turn, has made the underpressure receptacle less expensive. Conventionally, these underpressure receptacles have been made of metal and heated from the outside, so that a middle portion of a tubular underpressure receptacle was placed in an oven such that an end of the underpressure receptacle comprising the installation hatch extended out of the oven far enough for the elastomer seals of the hatch to be kept sufficiently cool. Tubular source, reaction and discharge pipeworks were provided inside the tubular vacuum chamber, which had to be introduced into the reactor through end flanges thereof. Fittings were provided into the wall of the tubular vacuum chamber for the pump line at most, and even these pump line fittings were placed close to the end flanges of the vacuum chamber.

A problem with the above-described arrangement is that connecting the source fittings to be introduced into the vacuum chamber through the service hatch, i.e. the rear flange, is a difficult task which has to be carried out by means of blind connections, since a user cannot actually see the connections. In addition, the structure of the reactor is such that the fittings to be introduced into the vacuum chamber are subjected to stress during recurring heating cycles.

The prior art has also employed underpressure chambers having the shape of a cube and containing heat sources and a reaction chamber. In such a vacuum chamber, solid sources were situated above and below a reaction zone or, alternatively, on the sides in two rows. The fittings for solid and liquid/gaseous sources were situated in the rear flange, and the vacuum chamber was loaded and/or the reaction chamber was installed through an installation hatch, i.e. a front hatch. The pump line was also provided through the rear flange. A problem with this solution was that the sources had to be combined using complex intermediate pipes containing a large number of connections, so that the sources were difficult to load and unload and it took two persons to service them. In addition, resistors for internal heating of the vacuum chamber were coupled to the same rear flange as the source fittings, which made them difficult to service. In a solution, resistor connections are also provided in a wall of the vacuum chamber such that they comprise several separate resistor pins. However, the solution is expensive and it increases the number of leadthroughs.

### BRIEF DESCRIPTION OF THE INVENTION

An object of the invention is thus to provide a reactor for an ALD method so as to enable the aforementioned problems to be solved. The object of the invention is achieved by a reactor which is characterized in that the reactor comprises a vacuum chamber containing a reaction chamber and having a first end wall provided with an installation hatch, a second end wall provided with a service hatch, side walls/casing connecting the first and the second end walls, and at least one source material fitting for feeding source materials into the vacuum chamber of the reactor.

Preferred embodiments of the invention are disclosed in the dependent claims.

The invention is based on the idea of changing the structure of an ALD reactor such that a source fitting is provided on the sides of a vacuum chamber of the reactor rather than in a rear flange, i.e. a service hatch, behind the vacuum chamber, as is the case with the prior art solutions. The vacuum chamber of the reactor thus comprises an installation hatch in its first end wall and a service hatch in its second end wall, resistors preferably being provided in the service hatch for heating the vacuum chamber of the reactor. In the present context, an installation hatch refers to an openable hatch and/or wall which enables a reaction chamber and other devices to be introduced into the vacuum chamber to be installed therethrough. A service hatch, in turn, refers to a rear flange situated opposite to the installation hatch. Side walls constituting the sides of the vacuum chamber extend between the first and the second end walls of the vacuum chamber. Depending on the shape of the vacuum chamber, the side walls are walls extending between the end walls. The invention is thus not restricted to a vacuum chamber of a certain shape, but the vacuum chamber may have the shape of e.g. a cube or a rectangular prism. The vacuum chamber may also have the shape of e.g. a cylinder, in which case the cylinder casing constitutes a side wall of the vacuum chamber. In accordance with the invention, source material fittings and also possible other gas fittings to be introduced into such a vacuum chamber are connected to the side wall or side walls of the vacuum chamber between the first and the second end wall. In other words, no source material fittings are preferably provided in the openable installation and service hatches.

An advantage of the method and arrangement of the invention is that when the source material fittings are connected to the side walls of the vacuum chamber, feed pipes for source material fittings to the reactor becomes simple and linear and, in addition, the source fitting connections are situated such that they can be checked visually. Consequently, it becomes possible for one person to install and disassemble the source material fittings. In addition, since the rear flange no longer comprises source material fittings, the heating elements may be safely provided in the rear flange, which also enables extension parts to be connected thereto, when necessary. Furthermore, the structure of the installation and service hatches becomes simpler.

### BRIEF DESCRIPTION OF THE DRAWINGS

The invention is now described in closer detail in connection with preferred embodiments and with reference to the accompanying drawings, in which:

FIGURE 1 is a schematic view showing a side view of an embodiment of a vacuum chamber according to the invention.

### DETAILED DESCRIPTION OF THE INVENTION

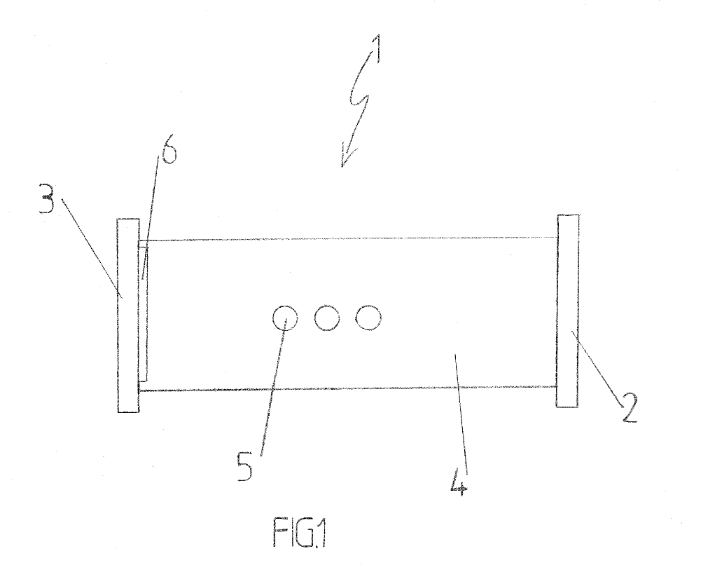

FIGURE 1 is a schematic view showing a side view of an embodiment of a vacuum chamber 1 according to the invention. In this exemplary embodiment, the vacuum chamber 1 has the shape of a cylinder, but it may also have any other shape, such as a cube, rectangular prism, cone, polygonal prism, etc. According to FIGURE 1, the vacuum chamber 1 comprises a first end wall 2 and a second end wall 3. The first end wall 2 comprises an installation hatch to enable installation therethrough of a reaction chamber and possibly also other devices to be provided inside the vacuum chamber. Alternatively, the installation hatch may also comprise a charging hatch to enable a product to be processed to be inserted into the vacuum chamber and to be removed therefrom. The second end wall 3, in turn, constitutes a rear flange, i.e. a service hatch, of the vacuum chamber. The vacuum chamber 1 usually further comprises a reaction chamber (not shown) installed inside the vacuum chamber.

The first and the second end walls 2, 3 are connected by a side wall, i.e. cylinder casing 4. When the vacuum chamber has the shape of a cube or a rectangular prism, the number of such side walls is four, and they connect the first and the second end walls 2, 3. Preferably, two of these side walls are substantially vertical while two are substantially horizontal, so that these substantially horizontal side walls constitute an upper side wall and a lower side wall.

According to FIGURE 1, source material fittings 5, the number of which may be one or more, for feeding chemicals into the vacuum chamber are provided in the casing 4, i.e. in the side wall of the vacuum chamber. In this embodiment, the source material fittings 5 are introduced into the vacuum chamber through the casing 4 substantially transversely with respect to the casing, i.e. substantially parallelly with the surfaces of the end walls 2, 3. The source material fittings 5 may further be introduced through the casing perpendicularly thereto. In a preferred embodiment, these source material fittings 4 extend horizontally through the vacuum chamber casing, which makes them maximally easy to handle while the reactor is in operation. When necessary, the source material fittings 5 may also be introduced through the casing such that they extend obliquely upwards or downwards or even directly upwards or downwards from the vacuum chamber. When desired, the source material fittings 5 may, however, be passed through the casing 5 obliquely, so that they may be directed towards either one of the first and the second end wall 2, 3. It is to be noted that the aforementioned remarks disclosed in connection with the casing of the cylindrical vacuum chamber also apply to vacuum chambers having another shape, such as a cube and a rectangular prism.

The source material fittings 5 may comprise source fittings for gaseous, liquid and solid source materials. This enables fittings for the inflow and discharge of a powdery source material to be provided in the upper and lower side walls of e.g. a cubical vacuum chamber. It is to be noted that in the present description, a source material fitting refers to a fitting for both the inflow and discharge of source materials. In some cases, the fittings provided in the side walls or the casing of the vacuum chamber may also be utilized for feeding elongated work pieces, products to be processed in the reactor, such as wires, fibres, bars, tubes, etc. through the reactor. In such a case, the vacuum chamber comprises at least two source material fittings provided, preferably situated so as to match one another, in opposite side walls of the vacuum chamber or on opposite sides of the casing 4, which enables the elongated work piece to be fed through the vacuum chamber via the aforementioned fittings. Such a structure of the reactor enables flow-through of piece goods, which was impossible with conventional reactors. The flow-through in the reactor may take place not only horizontally but also vertically, or at another angle. Similarly, a work piece may be fed and removed through the front and rear flanges. In addition to being solid, the work piece may also be powdery, granulate, chainlike, or it may consist of small components.

The solution according to the invention may also be utilized e.g. by taking other fittings to be provided into the vacuum chamber to the vacuum chamber through the side walls of the vacuum chamber. These fittings may comprise underpressure fittings, reaction fittings, discharge fittings, pump fittings, or the like.

In FIGURE 1, an end part, which constitutes a rear flange, is provided with a heat source 6 which constitutes an internal heat source. The heat source may be implemented with resistors which produce mainly cylinder symmetrical heating. Alternatively, the heat source may also be rectangular, or based on a direct contact with the piece/reaction chamber. A heat source installed in the rear flange is easy to pull out for cleaning. For this purpose, the reactor may be provided with a slipper bracket mechanism for supporting the rear flange while it is being pulled out. The slipper bracket mechanism also makes the flange easier to install and service. A heat source installed in the rear flange is easy to manufacture, service and clean, and the internal volume of the vacuum chamber is utilized efficiently. Instead of resistors, another radiating heat source may be used.

Instead of the internal heating of the vacuum chamber, external heating may be used which is implemented by an external heat source. No need then exists to provide a heat source inside the vacuum chamber, which is particularly advantageous when low process temperatures are used and/or when no need occurs to cool the vacuum chamber between process executions, or when continuous processing is used.

The rear flange of one end wall of the vacuum chamber may be further utilized to expand the reactor. This is simple and easy since the rear flange comprises no source material fittings that would otherwise make expanding the reactor difficult.

It is assumed in FIGURE 1 that the vacuum chamber 1 is in a horizontal position, but it is to be noted that the reactor may also be arranged in another position.

When the source material fittings 5 are situated in the side or sides of the vacuum chamber of an ALD reactor with respect to the installation hatch of the vacuum chamber, a user of the reactor is provided with direct access to the feed pipework for source material fittings. In addition, such a structure of the reactor enables the user to see the connections of the source material fittings uninterruptedly, which enables these sources to be assembled and disassembled by one person. Neither is it then necessary to detach the source material fittings for cleaning the vacuum chamber and, when necessary, the reactor may be expanded without touching the source material fittings. According to the invention, the source material fittings, with respect to a loading hatch, are provided on the sides of the vacuum chamber, between the end flanges, in which case they have been introduced into the vacuum chamber through its side walls/casing. However, it is to be noted that the invention does not restrict the direction in which the source material fittings are introduced into the vacuum chamber through the side walls/casing. The number of source material fittings may even be quite high and, when desired, they may be introduced into the vacuum chamber from different directions. The point is that no source material fittings are provided in the openable installation hatch. Hence, in the direction determined by this installation hatch and the rear flange, i.e. in the service direction, no gases are supplied to the reactor or discharged therefrom, but gases are provided transversely, in a gas direction, with respect to this service direction, through the side walls of the vacuum chamber.

It is apparent to one skilled in the art that as technology advances, the basic idea of the invention may be implemented in many different ways. The invention and its embodiments are thus not restricted to the above-described examples but may vary within the scope of the claims.

1-16. (canceled)

17. A reactor for an atomic layer deposition (ALD) method, the reactor comprising a vacuum chamber which contains a reactor chamber installed inside the vacuum chamber and which has a first end wall provided with an installation hatch, a second end wall provided with a service hatch, side walls/casing connecting the first and the second end walls, and at least one source material fitting for feeding source materials into the reactor chamber of the reactor, wherein that at least one of the source material fittings is arranged in the side wall/casing of the vacuum chamber of the reactor.

18. A reactor as claimed in claim 17, wherein the vacuum chamber has the shape of a cube, so that it comprises two substantially vertical side walls, at least one of which being provided with at least one source material fitting.

19. A reactor as claimed in claim 17, wherein the vacuum chamber has the shape of a rectangular prism, so that it comprises two substantially vertical side walls, at least one of which being provided with at least one source material fitting.

20. A reactor as claimed in claim 17, wherein the vacuum chamber further comprises a substantially horizontal upper and lower wall, at least one of which being equipped with a source fitting for powdery source materials.

21. A reactor as claimed in claim 17, wherein vacuum chamber has the shape of a cylinder, so that it comprises substantially circular first and second end walls and a casing provided with at least one source material fitting.

22. A reactor as claimed in claim 17, wherein the source material fitting or source material fittings is/are provided substantially transversely with respect to the side walls/casing.

23. A reactor as claimed in claim 22, wherein the source material fittings are provided substantially perpendicularly with respect to the side walls/casing.

24. A reactor as claimed in claim 17, wherein at least one of the source material fittings is provided in the vacuum chamber substantially horizontally.

25. A reactor as claimed in claims 17, wherein the vacuum chamber comprises at least two source material fittings matchingly provided on opposite of the vacuum chamber or on opposite sides of the casing.

26. A reactor as claimed in claim 17, wherein the vacuum chamber comprises at least two source material fittings to be utilized for feeding a work piece or work pieces through the vacuum chamber.

27. A reactor as claimed in claim 17, wherein the installation hatch and the service hatch are provided to enable the work piece to be fed through the vacuum chamber.

28. A reactor as claimed in claim 17, wherein the vacuum chamber comprises an internal heat source.

29. A reactor as claimed in claim 28, wherein the service hatch is provided with resistors for heating the vacuum chamber.

30. A reactor as claimed in claim 17, wherein the vacuum chamber comprises an external heat source.

31. A reactor as claimed in claim 17, wherein the reactor further comprises a slipper bracket mechanism for supporting the service hatch while it is being pulled out.

32. A reactor as claimed in claim 17, wherein the reactor further comprises underpressure means for generating underpressure in the vacuum chamber.
